(19) United States
(12) Patent Application Publication
(10) Pub. No.: US 2018/0306175 A1
(43) Pub. Date: Oct. 25, 2018

(54) MAGNETIC FOCUSING IN AN ION PUMP USING INTERNAL FERROUS MATERIALS

(71) Applicant: Edwards Vacuum LLC, Sanborn, NY (US)

(72) Inventors: Anthony Wynohrad, Osage, IA (US); Joel Langeberg, Lonsdale, MN (US)

(21) Appl. No.: 15/496,684

(22) Filed: Apr. 25, 2017

(51) Int. Cl. F04B 37/04; F04B 37/14; H01J 27/02; H01J 37/08; H01J 27/04

(52) U.S. Cl. CPC F04B 37/04; F04B 37/14; H01J 27/04; H01J 37/08; H01J 27/024

(57) ABSTRACT

An ion pump has an exterior magnet and a chamber wall defining an interior. The interior contains an anode having an exterior surface extending around an axis and defining an opening wherein the axis passes through the opening and a post made of ferrous material, aligned with the axis of the anode and positioned between the exterior magnet and the anode.

### BACKGROUND

Ultra-high vacuum is a vacuum regime characterized by pressures lower than 10⁻⁷ pascal (10⁻⁹ mbar, approximately 10⁻⁹ tor). Ion pumps are used in some settings to establish an ultra-high vacuum. In an ion pump, an array of cylindrical anode tubes are arranged between two cathode plates such that the openings of each tube faces one of the cathode plates. An electrical potential is applied between the anode and the cathode. At the same time, magnets on opposite sides of the cathode plates generate a magnetic field that is aligned with the axes of the anode cylinders.

The ion pump operates by trapping electrons within the cylindrical anodes through a combination of the electrical potential and the magnetic field. When a gas molecule drifts into one of the anodes, the trapped electrons strike the molecule causing the molecule to ionize. The resulting positively charged ion is accelerated by the electrical potential between the anode and the cathode toward one of the cathode plates leaving the stripped electron(s) in the cylindrical anode to be used for further ionization of other gas molecules. The positively charged ion is eventually trapped by the cathode and is thereby removed from the evacuated space. Typically, the positively charged ion is trapped through a sputtering event in which the positively charged ion causes material from the cathode to be sputtered into the vacuum chamber of the pump. This sputtered material coats surfaces within the pump and acts to trap additional particles moving within the pump. Thus, it is desirable to maximize the amount of sputtered material.

The discussion above is merely provided for general background information and is not intended to be used as an aid in determining the scope of the claimed subject matter. The claimed subject matter is not limited to implementations that solve any or all disadvantages noted in the background.

### SUMMARY

An ion pump has an exterior magnet and a chamber wall defining an interior. The interior contains an anode having an exterior surface extending around an axis and defining an opening wherein the axis passes through the opening and a post made of ferrous material, aligned with the axis of the anode and positioned between the exterior magnet and the anode.

In a further embodiment, an ion pump includes a chamber, a magnet that is outside the chamber and an anode having a central axis within the chamber. Ferrous material is positioned within the chamber between the anode and the magnet such that magnetic flux lines extend from the ferrous material and are substantially parallel to the central axis of the anode within the anode.

In a still further embodiment, an assembly for an ion pump includes a ferrous structure extending along an axis and a hollow cylinder having an axis that is aligned with the axis of the ferrous structure.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 provides a sectional view of a prior art ion pump.

FIG. 2 provides an enlarged view of a portion of the prior art ion pump of FIG. 1 showing magnetic flux lines.

FIG. 3 provides a side-sectional view of the anode array of the prior art pump of FIG. 1 showing a binary representation of magnetic field strength within the array.

FIG. 4 provides a sectional view of an ion pump in accordance with a first embodiment.

FIG. 5 provides an enlarged view of a portion of the ion pump of FIG. 4 showing magnetic flux lines.

FIG. 6. provides a side sectional view of the anode array of the ion pump of FIG. 4 showing a binary representation of magnetic field strength within the array.

FIG. 7 provides a perspective view of a ferrous material plate having posts/raised portions of ferrous material extending from the plate.

FIG. 8 provides a sectional view of an ion pump in accordance with a second embodiment.

### DETAILED DESCRIPTION OF ILLUSTRATIVE EMBODIMENTS

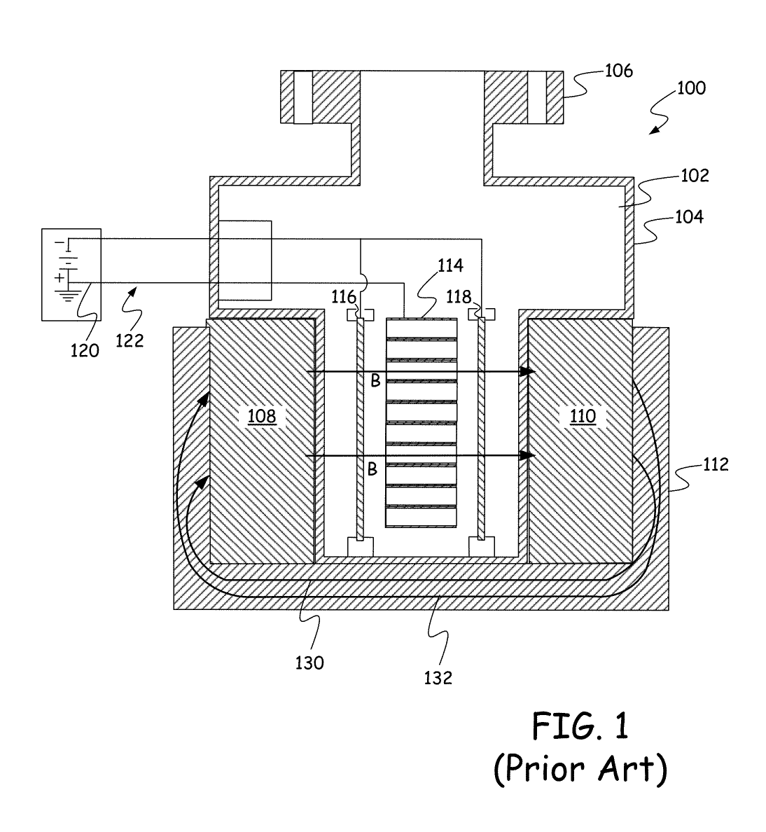

FIG. 1 provides a sectional view of a prior art ion pump 100. Ion pump 100 includes a vacuum chamber 102 defined by a chamber wall 104 that is welded to a connection flange 106 for connection to a system to be evacuated. Two ferrite magnets 108 and 110 are located external to chamber wall 104 and are mounted on opposing sides of ion pump 100. A magnetic flux guide 112 is positioned on the outside of each of ferrite magnets 108 and 110 and extends below ion pump 100 to guide magnetic flux between the exteriors of each of the ferrite magnets 108 and 110 as shown by arrows 130 and 132. Ferrite magnets 108 and 110 produce a magnetic field B that passes through vacuum chamber 102.

Within vacuum chamber 102, an array of cylindrical anodes 114 is positioned between two cathode plates 116 and 118 such that the openings of each anode cylinder face the cathode plates.

The cylindrical anodes 114 and chamber wall 104 are maintained at ground potential while cathode plates 116 and 118 are maintained at a negative potential by an external power supply 120 that is connected to ion pump 100 by a power cable 122. In accordance with some embodiments, the potential difference between cylindrical anode 114 and cathode plates 116 and 118 is 7 kV.

In operation, flange 106 is connected to a flange of a system to be evacuated. Once the flange is connected, particles within the system to be evacuated travel into vacuum chamber 102 and eventually move within the interior of one of the cylindrical anodes 114. The combination of the magnetic field B and the electrical potential between anodes 114 and cathode plates 116 and 118 cause electrons to be trapped within each of the cylindrical anodes 114. Although trapped within the cylindrical anodes 114, the electrons are in motion such that as particles enter a cylindrical anode 114, they are struck by the trapped electrons causing the particles to ionize. The resulting positively charged ions are accelerated by the potential difference between anode 114 and the cathode plates 116 and 118 causing the positively charged ions to move from the interior of cylindrical anodes 114 toward one of the cathode plates 116 and 118.

Some cathode plates of the prior art included target areas made up of angled faces. The angled faces are designed to change the angle at which the positive ions strike cathode plates 116 and 118 so that the ions strike the target at an angle that will cause material from the target to sputter outwardly away from cathode plate 116/118 and to cause the ion to become embedded in cathode plate 116/118.

The efficiency of the ion pump is a function of the number of electrons that can be maintained within the interior of cylindrical anodes 114. If more moving electrons can be maintained in anode 114, then more collisions will occur and more molecules will be ionized and captured. Stronger magnetic fields are better at trapping electrons than weaker magnetic fields. In many systems, the goal is to create a magnetic field of at least 1200 Gauss within the interior of each anode 114. This is difficult to achieve because along the perimeter of the anodes, the magnetic field bulges outward.

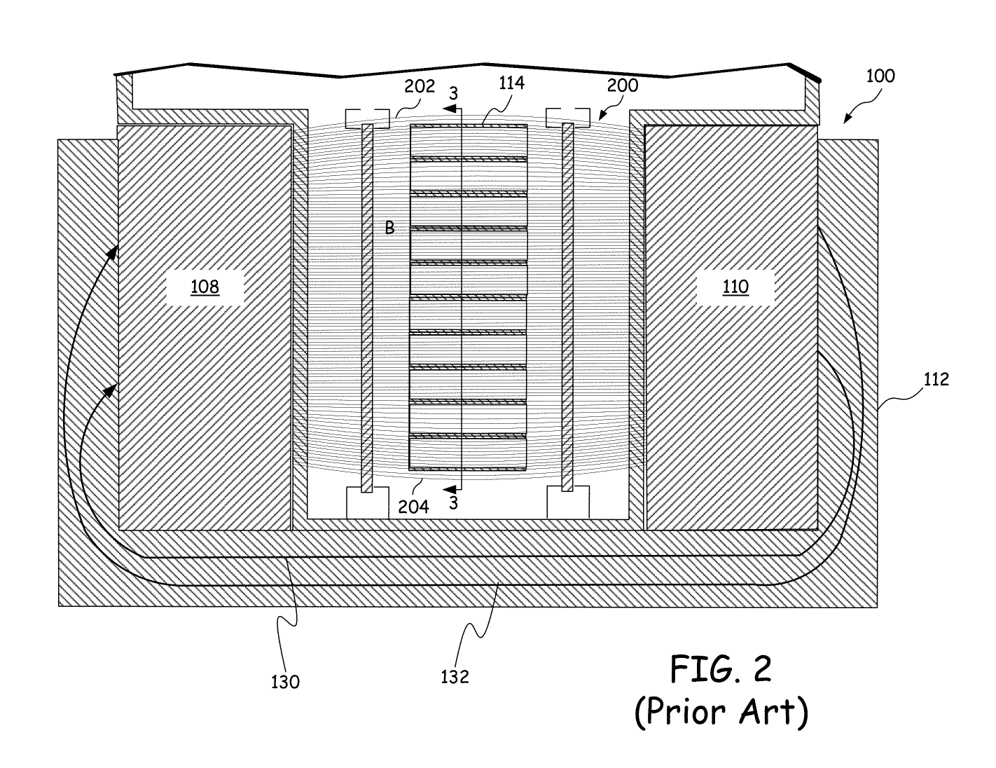

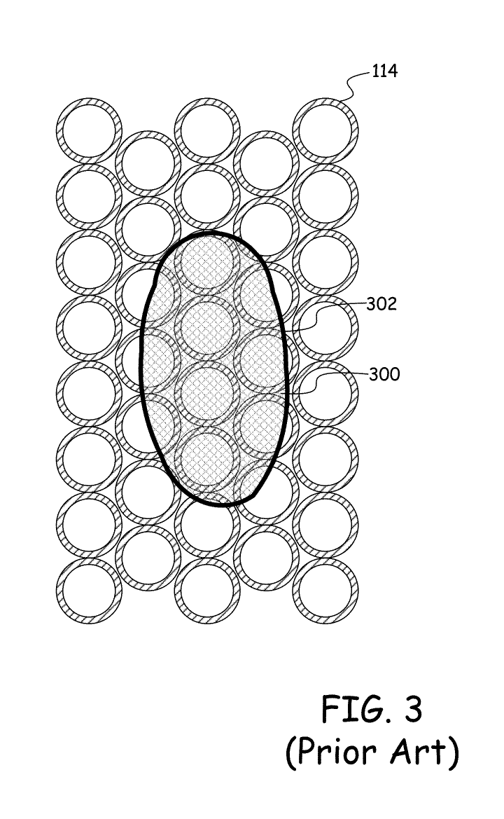

FIG. 2 provides an enlarged view of a portion of ion pump 100 showing flux lines 200 for the magnetic field between magnets 108 and 110. As shown in FIG. 2, the magnetic flux lines bend upward at the top of anodes 114, such as magnetic flux line 202, and downward at the bottom of anodes 114, such as magnetic flux line 204. Similar bending occurs at the outer sides of the array of anodes 114. This bending coincides with a reduction in the magnetic field strength in the perimeter anodes as shown in FIG. 3.

FIG. 3 shows a sectional view of anodes 114 taken along line 3-3 of FIG. 2. In FIG. 3, a binary representation of the magnetic field strength is depicted with areas where the magnetic field strength is below a threshold depicted without shading and areas where the magnetic field strength is above the threshold shown with shading 300. A closed surface 302 separates the two areas. In one embodiment, the threshold field strength is 1200 Gauss (0.12 Tesla). As shown in FIG. 3, where the flux lines bulge outward along the perimeter of the array of anodes 114, the field strength in the perimeter anodes is less than the field strength in the interior anodes, resulting in inefficient pumping in the perimeter anodes.

In addition, because the flux lines bulge in the perimeter anodes, the flux lines are not parallel to the axis of the cylindrical anodes. Because of this, the electrons in the anodes tend to move along the flux lines in a helical pattern until reaching the portion of the flux lines that minimizes the electrical potential of the electron. Thus, the electrons will move along the curved flux lines in a direction that brings them closer to the cylindrical body of the anodes. Often, during this movement, the electron will strike the anode and thereby be released from the trap. Thus, having bends in the flux lines within the anodes reduces the efficiency of ion pumping.

The embodiments described below provide improved ion pumps that strengthen the magnetic field in many of the anode cylinders and better align the flux lines of the magnetic field with the axes of the anode cylinders to better trap electrons within the anodes.

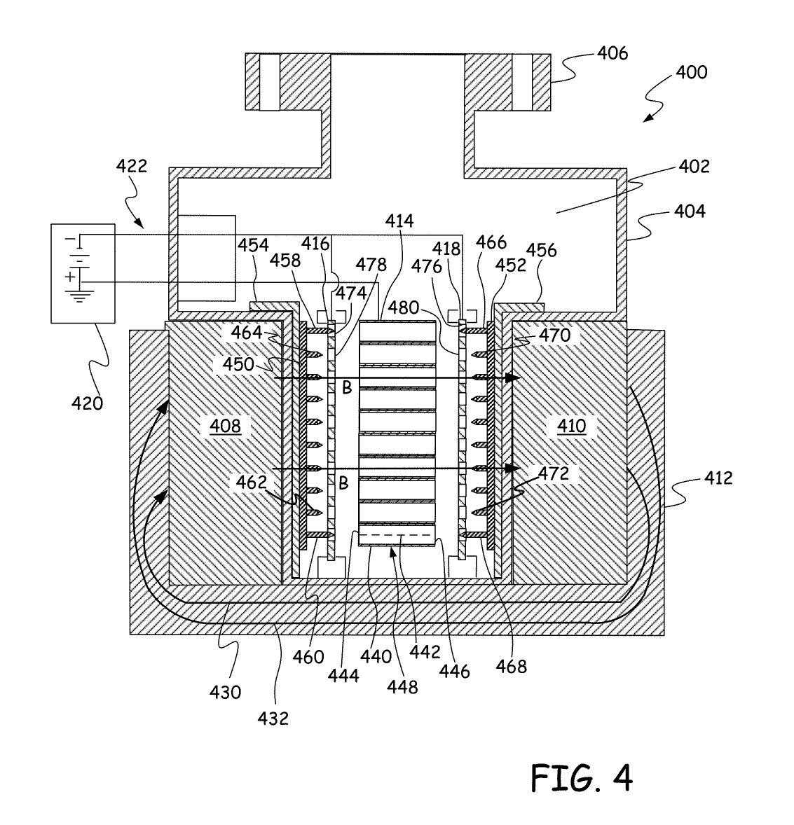

FIG. 4 provides a side sectional view of one embodiment of an ion pump 400 that provides these improved magnetic field characteristics. Ion pump 400 includes a vacuum chamber or interior 402 defined by a chamber wall 404 that is welded to a connection flange 406 for connection to a system to be evacuated. Two external ferrite magnets 408 and 410 are located external to chamber wall 404 and are mounted on opposing sides of ion pump 400. Magnetic flux guide 412 is positioned on the outside of the ferrite magnets 408 and 410 and extends below ion pump 400 to guide magnetic flux between the exteriors of each of ferrite magnets 408 and 410 as shown by arrows 430 and 432. Ferrite magnets 408 and 410 produce a magnetic field B that passes through vacuum chamber 402.

Within vacuum chamber 402, an array of hollow cylindrical anodes 414 is positioned between two cathode plates 416 and 418 such that the openings of each anode cylinder face the cathode plates. In particular, each anode, such as anode 440, has a central axis 442 that passes through two openings 444 and 446 of the cylindrical anode. The exterior surface 448 of the cylindrical anode extends around central axis 442. In accordance with most embodiments, cylindrical anodes 414 are made of a non-ferrous material.

The cylindrical anodes 414 and chamber wall 404 are maintained at ground potential while cathode plates 416 and 418 are maintained at a negative potential by an external power supply 420 that is connected to ion pump 400 by a power cable 422. In accordance with some embodiments, the potential difference between cylindrical anodes 414 and cathode plates 416 and 418 is 7 kV.

In operation, flange 406 is connected to a flange of a system to be evacuated. Once the flanges are connected, particles within the system to be evacuated travel into vacuum chamber 402 and eventually move within the interior of one of the cylindrical anodes 414. The combination of the magnetic field B and the electrical potential between anodes 414 and cathode plates 416 and 418 cause electrons to be trapped within each of the cylindrical anodes 414. Although trapped within cylindrical anodes 414, the electrons are in motion such that as particles enter a cylindrical anode 414, they are struck by the trapped electrons causing the particles to ionize. The resulting positively charged ions are accelerated by the potential difference between anodes 414 and the cathode plates 416 and 418 causing the positively charged ions to move from the interior of cylindrical anodes 414 toward one of the cathode plates 416 and 418. When a positive ion strikes one of cathode plates 416 and 418, material from the cathode plates sputters away from the cathode plate and the ion reacts with the material of the cathode plate or an electron to neutralize the ion.

To strengthen the magnetic field and align the flux lines of the magnetic field with the axes of the cylindrical anodes, the embodiment of FIG. 4 provides ferrous structures within the interior/chamber 402 between anodes 414 and external magnets 408 and 410 such that magnetic flux lines extend from the ferrous structures and are substantially parallel to the central axes of the anode cylinders 414. In accordance with the embodiment of FIG. 4, the ferrous structures are raised portions or posts of ferrous material such as posts 458, 460, 462, 464, 466, 468, 470 and 472 that each extend along a respective axis. In some embodiments, the axis of each post is substantially the same as a respective axis of one of the anode cylinders 414. Thus, the raised portions of ferrous material extend toward a respective anode at the central axis of the respective anode. The posts/raised portions of ferrous material guide the magnetic fields generated by magnets 408 and 410, such that the magnetic flux lines extending from the raised portions/posts are better aligned with the axes of the cylindrical anodes within the cylindrical anodes thereby strengthening the magnetic field and providing straighter magnetic flux lines within the cylindrical anodes that are better able to trap electrons within the anodes.

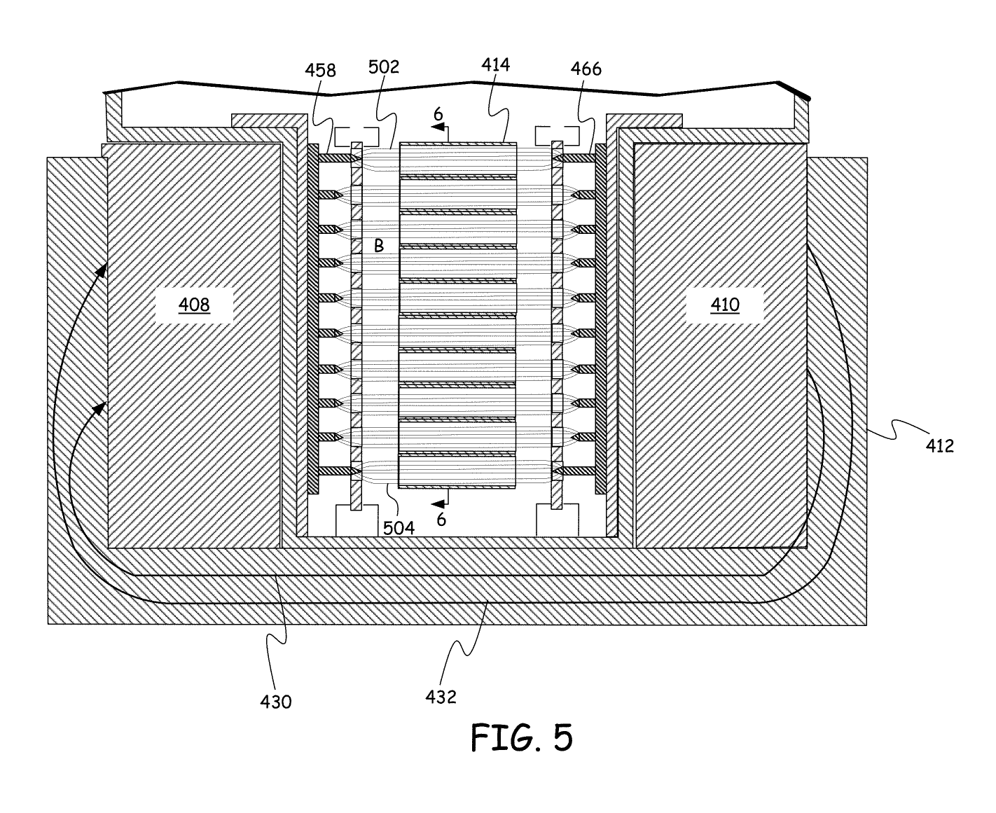

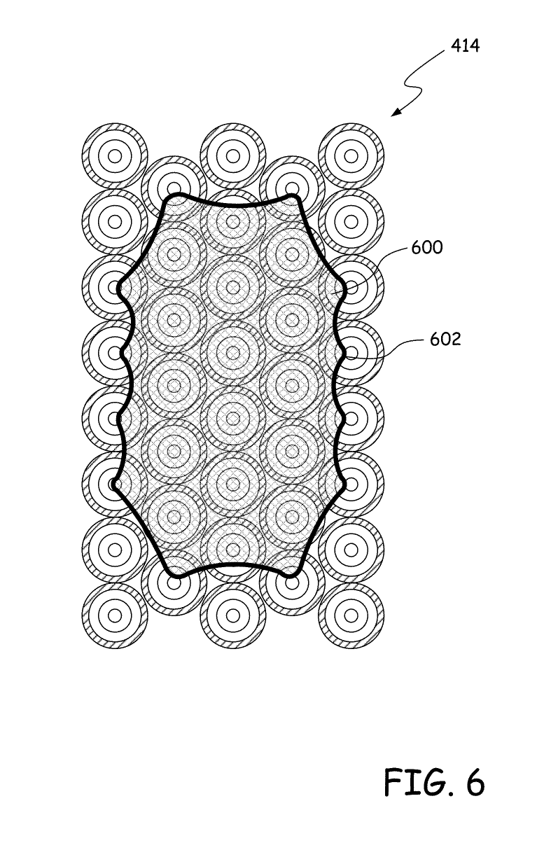

The effects of the raised portions/posts of ferrous material can be seen in FIGS. 5 and 6. In FIG. 5, an enlarged sectional view of FIG. 4 is shown that depicts the flux lines extending from the raised portions/posts of ferrous material within chamber 402. Comparing FIG. 5 to FIG. 2, it can be seen that flux lines 502 at the top of anode array 414 and flux lines 504 at the bottom of anode array 414 are straighter and better aligned with the axes of the cylindrical anodes than flux lines 202 and 204 at the top and bottom of cylindrical anodes 114 of FIG. 2 of the prior art. Similar straightening of the flux lines occurs in the cylindrical anodes at the sides of cylindrical anode array 414.

This results in a more uniform distribution of the magnetic field in the cylindrical anodes as shown in FIG. 6, which shows a sectional view taken along lines 6-6 of FIG. 5. In FIG. 6, a binary representation of the magnetic field strength is depicted with areas where the magnetic field strength is below a threshold depicted without shading and areas with magnetic field strengths above the threshold shown with shading 600. A closed surface 602 separates the two areas. In one embodiment, the threshold field strength is 1200 Gauss (0.12 Tesla). As shown in FIG. 6, by straightening the flux lines, the number of cylindrical anodes 414 that have a magnetic field strength above the threshold is larger in the present embodiment than in the prior art shown in FIG. 3. In accordance with some embodiments, a doubling of the number of anodes with a field strength above 1200 Gauss was achieved using the raised portions/posts of ferrous material, while using the same external magnets.

Returning to FIG. 4, the ferrous material in chamber 402 also includes a plate, such as plates 450 and 452 where the raised portions/posts are connected to and extend from plates 450 and 452 toward anodes 414. The ferrous material of plates 450, 452 and posts 458-472 can be any desired ferrous material including ASTM 1018 steel, nickel, and Mu-metal, for example. In accordance with one embodiment, plates 450 and 452 are tack welded to support structures 454 and 456, respectively. Support structures 454 and 456 have an L-shape that conforms to a shape of chamber wall 404 to stably mount structures 454 and 456 to chamber wall 404. In one embodiment, structures 454 and 456 are made of a non-magnetic material, such as stainless steel.

In accordance with the embodiments shown in FIG. 4, cathode plates 416 and 418 include openings or holes that have a central axis aligned with the axis of the ferrous material posts/raised portions. For example, openings 474 and 476 are aligned with the axes of posts 458 and 466, respectively and openings 478 and 480 are aligned with the axes of posts 464 and 470, respectively. As shown in FIG. 4, at least some of the openings in the cathode plates 416 and 418 allow a portion of a post/raised portion of ferrous material to extend into cathode plates 416 and 418. For example opening 464 allows post 458 to extend into cathode plate 416. Thus, the openings in the cathode plates 416 and 418 allow longer posts/raised portions of ferrous material to be included in chamber 402 without increasing the distance between magnets 408 and 410. This allows ferrous material to be placed closer to anode cylinders 414 allowing for better guidance of the magnetic flux lines within anode cylinders 414.

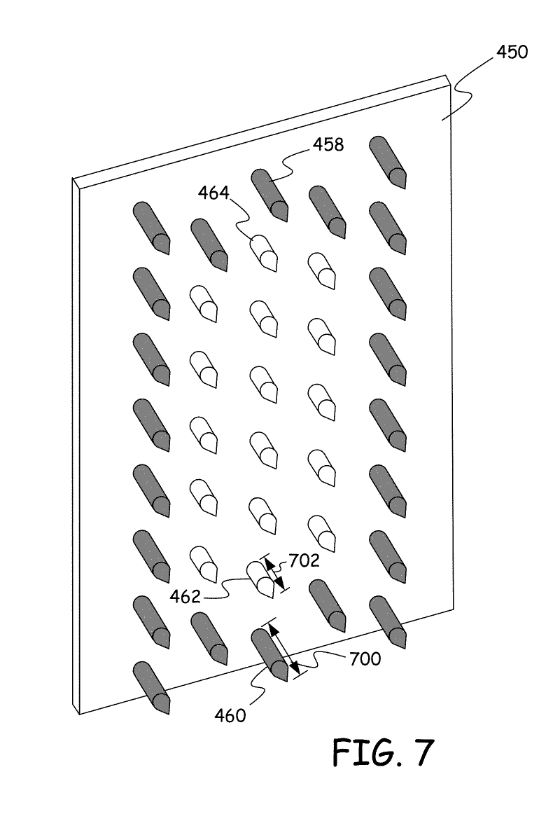

FIG. 7 provides a perspective view of ferrous material plate 450 and the posts/raised portions of ferrous material connected to and extending from plate 450, such as posts 458, 460, 462 and 464, in accordance with one embodiment. As shown in FIG. 7, an array of posts/raised portions of ferrous material extends from plate 450 with the array including perimeter posts/raised portions of ferrous material shown in dark shading and interior posts/raised portions shown in light shading. For example, posts 462 and 464 are interior posts/raised portions and posts 460 and 458 are perimeter posts/raised portions. The perimeter posts/raised portions extend around the interior posts/raised portions and each of the perimeter raised portions extends into a respective opening in the cathode plate. In addition, the exterior posts/raised portions have a length, such as length 700 of post 460, that is longer than a length of the interior posts/raised portions, such as length 702 of post 462. In FIG. 7, lengths 700 and 702 are the distances from the point on the posts closest to the anode cylinders to the surface of plate 450 facing the anode cylinders. As shown in FIG. 7, the perimeter posts/raised portions extend closer to the anodes than the interior posts/raised portions.

Although the embodiment of FIGS. 4 and 7 show cylindrical posts with conical ends for the posts/raised portions, the invention is not limited to such shapes. Other embodiments use other shapes for the posts/raised portions including n-sided posts such as 4-sided square posts, and flat or domed ends on the posts, for example.

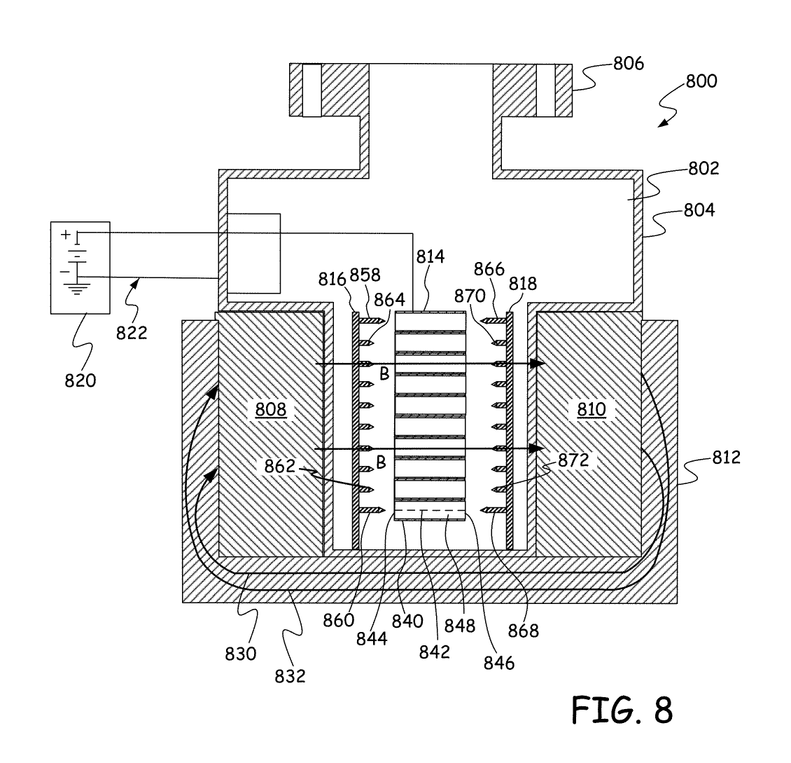

FIG. 8 provides a sectional view of an ion pump 800 in accordance with a second embodiment in which ferrous material is placed inside a vacuum chamber 802. Ion pump 800 includes a vacuum chamber/interior 802 defined by a chamber wall 804 that is welded to a connection flange 806 for connection to a system to be evacuated. Two external ferrite magnets 808 and 810 are located external of chamber wall 804 and are mounted on opposing sides of ion pump 800. A magnetic flux guide 812 is positioned on the outside of each of ferrite magnets 808 and 810 and extends below ion pump 800 to guide magnetic flux between the exteriors of each of the ferrite magnetics 808 and 810 as shown by arrows 830 and 832. Ferrite magnets 808 and 810 produce a magnetic field B that passes through vacuum chamber 802. Within vacuum chamber 802, an array of cylindrical anodes 814 is positioned between two cathode plates 816 and 818 such that the openings of each anode cylinder face the cathode plates. Cathode plate 816 is positioned between external magnet 808 and anodes 814 while cathode plate 818 is positioned between external magnet 810 and anodes 814. In the embodiment of FIG. 8, cathode plates 816 and 818 are made of ferrous material and include posts/raised portions of ferrous material, such as posts 858, 860, 862, 864 on cathode plate 816 and posts/raised portions 866, 868, 870 and 872 on cathode plate 818. In accordance with one embodiment, cathode plates 816 and 818 have a similar configuration to plate 450 and its associated posts/raised portions of ferrous material shown in FIG. 7. In FIG. 8, cathode plates 816, 818 and chamber wall 804 are maintained at ground potential while anodes 814 are maintained at a positive potential by an external power supply 820 that is connected to ion pump 800 by a power cable 822. In accordance with some embodiments, the potential difference between cylindrical anodes 814 and cathode plates 816 and 818 is 7 kV.

Cylindrical anodes 814 have a central axis, such as axis 842 of anode 840 where an exterior surface 848 of anode 840 extends around central axis 842. The central axis of each anode 814 passes through two openings in the anode, such as openings 844 and 846 of anode 840. Each post/raised portion of ferrous material on cathode plates 816 and 818 extends along an axis that is substantially the same as an axis of a respective cylindrical anode 814.

In operation, flange 806 is connected to a flange of a system to be evacuated. Once the flanges are connected, particles within the system to be evacuated travel into vacuum chamber 802 and eventually move within the interior of one of the cylindrical anodes 814. The combination of magnetic field B and the electrical potential between anodes 814 and cathode plates 816 and 818 cause electrons to be trapped within each of the cylindrical anodes 814. Although trapped within the cylindrical anodes 814, the electrons are in motion such that when particles enter a cylindrical anode 814 the particles are struck by the trapped electrons causing the particles to ionize. The resulting positively charged ions are accelerated by the potential difference between anode 814 and the cathode plates 816 and 818 causing the positively charged ions to move from the interior of cylindrical anodes 814 toward one of the cathode plates 816 and 818.

In accordance with one embodiment, cathode plates 816 and 818 are formed of a ferrous material coated with a sputtering material, such as titanium. As the ions strike the sputtering material, they cause the sputtering material to sputter outwardly from cathode plates 816/818 and the ion reacts with the sputtering material or an electron of cathode plate 816/818. In some embodiments, the posts/raised portions of ferrous material are also coated with a layer of sputtering material, such as titanium.

The posts/raised portions of ferrous material of cathode plates 816 and 818 direct the magnetic field generated by magnetics 808 and 810 such that magnetic flux lines extend from the posts/raised portions of ferrous material and are substantially parallel to the central axis of the anodes within the anodes 814. This creates straighter magnetic flux lines within the anodes 814 and increases the number of anodes in which the magnetic field strength exceeds a threshold resulting in field lines similar to those shown for the embodiment of FIG. 4 in FIGS. 5 and 6.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms for implementing the claims.

What is claimed is:

1. An ion pump comprising:
an exterior magnet;
a chamber wall defining an interior that contains a set of elements comprising:
an anode having an exterior surface extending around an axis and defining an opening wherein the axis passes through the opening; and
a post made of ferrous material, aligned with the axis of the anode and positioned between the exterior magnet and the anode.

2. The ion pump of claim 1 wherein the magnetic post is part of a cathode.

3. The ion pump of claim 1 wherein the set of elements further comprises:
a plate made of ferrous material wherein the post is connected to and extends from the plate toward the anode.

4. The ion pump of claim 3 further comprising a cathode positioned between the plate and the anode.

5. The ion pump of claim 4 wherein the cathode comprises a cathode plate having at least one hole and wherein the post is aligned with the at least one hole.

6. The ion pump of claim 5 wherein the post extends into the at least one hole.

7. The ion pump of claim 1 wherein the post has a length and wherein the set of elements further comprises:
a second anode having a respective exterior surface extending around a respective axis and defining a respective opening wherein the respective axis passes through the respective opening; and
a second post made of ferrous material, aligned with the respective axis of the second anodes, positioned between the exterior magnet and the second anode and having a length that is shorter than the length of the post.

8. The ion pump of claim 7 wherein the post and the second post are in an array of posts, with the post forming part of a perimeter of the array of posts and the second post forming part of an interior of the array of posts.

9. An ion pump comprising:
a chamber;
a magnet that is outside the chamber;
an anode having a central axis within the chamber; and
ferrous material within the chamber between the anode and the magnet such that magnetic flux lines extend from the ferrous material and are substantially parallel to the central axis of the anode within the anode.

10. The ion pump of claim 9 further comprising a plurality of anodes each having a respective central axis wherein the ferrous material comprises a plurality of raised portions, with each raised portion extending toward a respective anode at the central axis of the respective anode.

11. The ion pump of claim 10 wherein the ferrous material forms a cathode.

12. The ion pump of claim 10 further comprising a cathode positioned between the anode and the magnet.

13. The ion pump of claim 12 wherein the cathode comprises a plate having openings wherein each raised portion of ferrous material is aligned with a respective opening.

14. The ion pump of claim 13 wherein at least one raised portion extends into an opening of the cathode plate.

15. The ion pump of claim 14 wherein a plurality of raised portions comprise perimeter raised portions and interior raised portions wherein the perimeter raised portions extend around the interior raised portions and each of the perimeter raised portions extend into a respective opening in the cathode plate.

16. The ion pump of claim 15 wherein the perimeter raised portions extend closer to the plurality of anodes than the interior raised portions.

17. An assembly for an ion pump comprising:
a ferrous structure extending along an axis;
a hollow cylinder having an axis that is aligned with the axis of the ferrous structure.

18. The assembly of claim 17 wherein the hollow cylinder forms an anode.

19. The assembly of claim 18 wherein the ferrous structure forms a cathode.

20. The assembly of claim 17 further comprising a cathode.

21. The assembly of claim 20 wherein the cathode comprises a plate having an opening aligned with the axis of the ferrous structure.

22. The assembly of claim 21 wherein the ferrous structure extends into the opening.
